(19) United States
(12) Patent Application Publication
(10) Pub. No.: US 2011/0107167 A1
(43) Pub. Date: May 5, 2011

(54) METHOD AND APPARATUS FOR TRANSMITTING AND RECEIVING FREQUENCY CHANNEL INFORMATION

(75) Inventor: Jun-yeub Lee, Seoul (KR)

(73) Assignee: SAMSUNG ELECTRONICS CO., LTD., Suwon-si (KR)

(21) Appl. No.: 13/000,893

(22) PCT Filed: Nov. 28, 2008
(86) PCT No.: PCT/KR2008/007017

§ 371 Date: Dec. 22, 2010

(30) Foreign Application Priority Data
Jun. 25, 2008 (KR) 10-2008-0060222

(51) Int. Cl. H03M 13/00; H04W 72/04

(52) U.S. Cl. 714/746; 370/329; 714/E11.001

(57) ABSTRACT

A method of transmitting frequency channel information by a device to which a frequency band is allocated so as to implement frequency sharing without affecting primary services. The method includes: modulating a stream having content into a main signal; generating a channel information signal related to the frequency band allocated to the device; and combining and transmitting the modulated main signal and the channel information signal. Accordingly, frequency sharing can be used for various primary services by enabling a terminal device to obtain information on a used frequency band without increasing the complexity of the terminal device.

### CROSS REFERENCE TO RELATED PATENT APPLICATION

This application is a National Stage application under 35 U.S.C. §371 of PCT/KR2008/007017 filed on Nov. 28, 2008, which claims priority from Korean Patent Application No. 10-2008-0060222, filed on Jun. 25, 2008, in the Korean Intellectual Property Office, all the disclosures of which are incorporated herein in their entireties by reference.

### BACKGROUND

1. Technical Field

Apparatuses and methods consistent with exemplary embodiments relate to transmitting and receiving frequency channel information, and more particularly, to transmitting and receiving information on whether a frequency band is used in order to accomplish frequency sharing without affecting primary services.

2. Description of Related Art

With the development of wireless communication technology, frequency resources are increasingly valuable intangible assets. While petroleum, iron, gas, and other resources are important resources for a country, frequency resources are now as important as the above-listed resources to the information society of the 21st century. In the analogue age, wireless communication was restrictively used. However, with the recent commercialization of code division multiple access (CDMA) mobile communication, wireless communication technology has been dramatically developed and a ubiquitous information society will arrive before long. In such ubiquitous information society, however, since the demand for frequency resources surpasses supply, severe frequency scarcity is expected.

Since most frequencies below 6 GHz are already allocated and the supply of frequency resources for next generation mobile communications is expected to be much less than their demand, frequency sharing, which allows unused frequency resources to be efficiently used, is supposed to be a good solution to the scarcity of frequency resources. To this end, the concept of cognitive radio (CR) allowing various services to share a frequency spectrum has been introduced.

In addition, the international frequency-related policy is also being changed from one that guarantees only incumbent users to use their own frequency channels to one that permits frequency channels to be shared.

Accordingly, in order to implement frequency sharing, there is need for a technology that does not affect TV receivers of existing corporations, which provide primary services such as TV broadcasting services, and can accurately determine whether a frequency channel to be used is licensed to a primary user.

FIG. 1 is a graph illustrating a frequency spectrum used by the conventional art.

Referring to FIG. 1, distributed frequencies have an average frequency utilization rate of approximately 30%. A heavy use band 110 has a highest frequency utilization rate, a sparse use band 120 has a lowest frequency utilization rate, and a medium use band 130 has a middle frequency utilization rate.

Spectrum sensing is a main type of CR by which a CR terminal detects whether a primary service is used by using the time/frequency characteristics of a primary service signal. That is, spectrum sensing involves determining whether a primary user uses a specific frequency, and enabling a secondary user to use the specific frequency if it is determined that the primary user does not use the specific frequency.

FIG. 2 is a graph illustrating a conventional communication method using dynamic spectrum sensing.

CR is a combination of a software defined radio (SDR) communication technology and a computer-based cognitive technology that continuously gains knowledge of its environment by itself and processes events in the environment. CR involves searching a neighboring frequency spectrum, and communicating if a channel to which a specific frequency is allocated is vacant but moving to another frequency band if the specific frequency is used by a primary distributor, that is, an incumbent user, to communicate, thereby avoiding interference with the primary distributor. To this end, a CR device uses a quiet period to periodically detect whether the primary distributor uses the specific frequency even while using the specific frequency. If it is determined that the primary distributor uses the specific frequency, the CR device moves to another channel within a given time or stops using the specific frequency.

Referring to FIG. 2, a conventional CR device searches a spectrum and communicates based on a list of usable frequencies. In operation 210, the conventional CR device initially accesses a frequency F2 through dynamic spectrum access (DSA). In operation 220, the conventional CR device determines whether a primary distributor of the frequency F2 uses the frequency F2, and moves to a frequency F4 to communicate if it is determined that the primary distributor of the frequency F2 uses the frequency F2. In this case, if the bandwidth of the frequency F4 is wider than that of the frequency F2, the conventional CR device determines a transmission method suitable for the wider bandwidth. In operation 230, when the bandwidth increases over time, the conventional CR device increases a transmission capacity by using a wideband transmission technology. In operation 240, the conventional CR device determines whether a primary distributor of the frequency F4 uses the frequency F4 and moves to an unoccupied frequency F1 if it is determined that the primary distributor of the frequency F4 uses the frequency F4.

Accordingly, the conventional CR device can adaptively communicate according to an unoccupied frequency band and can control an output or a transmission method by using information on its environment.

However, the conventional CR device using dynamic spectrum sensing cannot 100 percent accurately detect whether a frequency is used, technically. Furthermore, the reliability of primary distributors on frequency sharing through such dynamic spectrum sensing is not high enough.

### SUMMARY

Exemplary embodiments provide a method and apparatus for transmitting and receiving information on frequency bands in order to implement frequency sharing without affecting primary services.

According to an aspect of an exemplary embodiment, there is provided a method of transmitting frequency channel information by a device to which a frequency band is allocated, the method comprising: modulating a stream having content into a main signal; generating a channel information signal related to the frequency band allocated to the device; and combining and transmitting the modulated main signal and the channel information signal.

The generating of the channel information signal may comprise generating the channel information signal as a separate signal from the modulated main signal.

The generated channel information signal may have a power level less than that of the main signal by a predetermined threshold value. The threshold value may be an experimental value that does not change an error rate of the main signal and is higher than 20 dB.

The generating of the channel information signal may further comprise modulating channel information by using spread spectrum.

The generating of the channel information signal may further comprise: converting the channel information into a stream having a predefined frame format; forward error control (FEC) encoding the converted stream; interleaving the encoded stream; and mapping the interleaved stream into a symbol data stream.

According to another aspect of an exemplary embodiment, there is provided a method of receiving frequency channel information by a second device that shares a frequency band allocated to a first device, the method comprising: receiving a channel information signal combined with a main signal having content; extracting the channel information signal by separating the channel information signal and the received main signal; and obtaining frequency channel information from the extracted channel information signal.

The received channel information signal may have a power level less than that of the main signal by a predetermined threshold value. The threshold value may be an experimental value that does not change an error rate of the main signal and is higher than 20 dB.

The extracting of the channel information signal may further comprise demodulating the channel information signal into a non-spread spectrum signal by using a despread spectrum.

The extracting of the channel information signal may further comprise obtaining synchronization with respect to the channel information signal by using a predefined frame format of the channel information signal. If the first device synchronizes the main signal with the channel information signal at the same start point of time, the extracting of the channel information signal may further comprise obtaining synchronization with respect to the channel information signal by using a frame format of the main signal.

The obtaining of the frequency channel information may further comprise: demapping the demodulated channel information signal into a bit data stream; deinterleaving the bit data stream; and FEC decoding the deinterleaved bit data stream.

According to another aspect of an exemplary embodiment, there is provided an apparatus for transmitting frequency channel information by a device to which a frequency band is allocated, the apparatus comprising: a main signal processing unit modulating a stream having content into a main signal; a channel information processing unit generating a channel information signal related to the frequency band allocated to the device; and a signal combining unit combining and transmitting the modulated main signal and the channel information signal.

The channel information processing unit may generate the channel information signal as a separate signal from the modulated main signal.

The generated channel information signal may have a power level less than that of the main signal by a predetermined threshold value. The threshold value may be an experimental value that does not change an error rate of the main signal and is higher than 20 dB.

The channel information processing unit may further comprise a spread spectrum unit modulating channel information by using spread spectrum.

The channel information processing unit may further comprise: a format converting unit converting the channel information into a stream having a predefined frame format; an encoder FEC encoding the converted stream; an interleaver interleaving the encoded stream; and a mapper mapping the interleaved stream into a symbol data stream.

According to another aspect of an exemplary embodiment, there is provided an apparatus for receiving frequency channel information by a second device that shares a frequency band allocated to a first device, the apparatus comprising: a signal receiving unit receiving a channel information signal combined with a main signal having content; an extracting unit extracting the channel information signal by separating the channel information signal and the received main signal; and a channel information processing unit obtaining frequency channel information from the extracted channel information signal.

The received channel information signal may have a power level less than that of the main signal by a predetermined threshold value. The threshold value may be an experimental value that does not change an error rate of the main signal and is higher than 20 dB.

The extracting unit may further comprise a despread spectrum unit demodulating the channel information signal into a non-spread spectrum signal by using despread spectrum.

The extracting unit may further comprise a synchronizing unit obtaining synchronization with respect to the channel information signal by using a predefined frame format. If the first device transmits the main signal and the channel information signal the same start point of time, the extracting unit may further comprise a synchronization unit obtaining synchronization with respect to the channel information signal by using a frame format of the main signal.

The channel information processing unit may comprise: a demapper demapping the demodulated channel information signal into a bit data stream; a deinterleaver deinterleaving the bit data stream; and a decoder FEC decoding the deinterleaved bit data stream.

According to another aspect of an exemplary embodiment, there is provided a computer-readable recording medium having embodied thereon a program for executing a method of transmitting or receiving frequency channel information.

The method and apparatus for transmitting and receiving the frequency channel information according to exemplary embodiments can implement frequency sharing without affecting existing primary services. The method and apparatus according to exemplary embodiments can use frequency sharing for various primary services by enabling a terminal device to obtain information on a used frequency band without increasing the complexity of the terminal device.

### BRIEF DESCRIPTION OF THE DRAWINGS

FIG. 1 is a graph illustrating a frequency spectrum used by the conventional art;

FIG. 2 is a graph illustrating a conventional communication method using dynamic spectrum sensing;

FIG. 3 is a flowchart illustrating a method of transmitting frequency channel information, according to an exemplary embodiment;

FIG. 4 is a flowchart illustrating a method of transmitting frequency channel information, according to another exemplary embodiment;

FIG. 5 is a flowchart illustrating a method of receiving frequency channel information, according to an exemplary embodiment;

FIG. 6 is a flowchart illustrating a method of receiving frequency channel information, according to another exemplary embodiment;

FIG. 7 is a block diagram of an apparatus for transmitting frequency channel information according to an exemplary embodiment; and

FIG. 8 is a block diagram of an apparatus for receiving frequency channel information according to an exemplary embodiment.

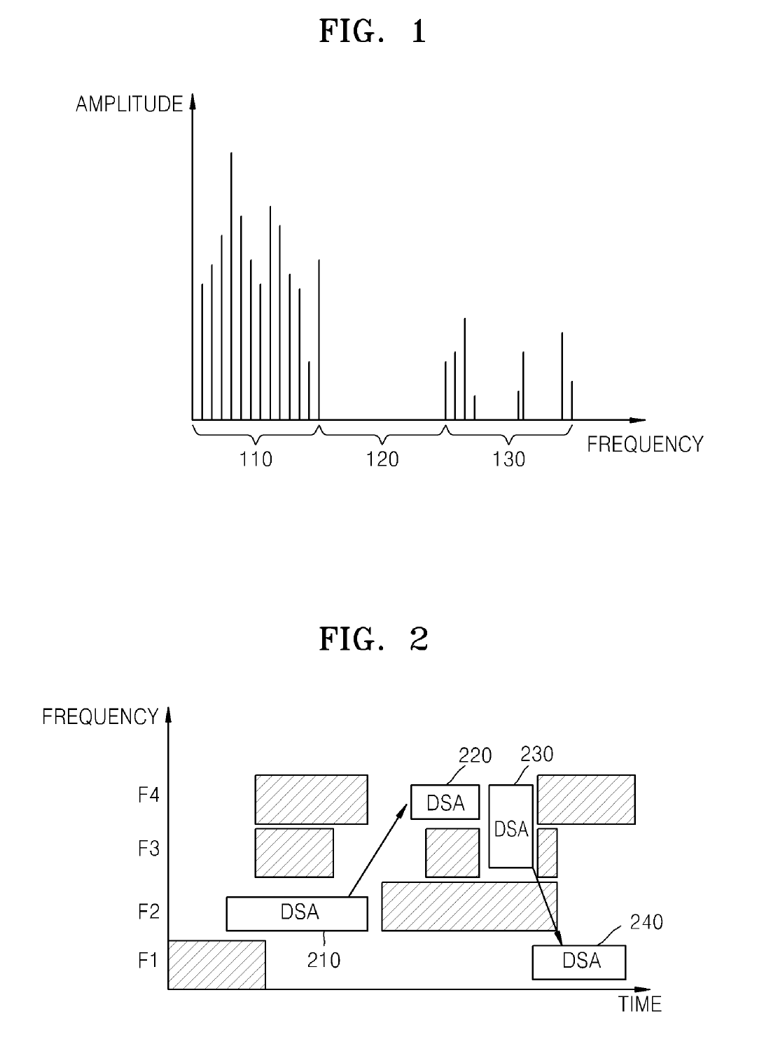

In the drawings, like reference numerals denote like elements. The accompanying drawings are intended to depict exemplary embodiments and should not be interpreted to limit the intended scope of the claims. The accompanying drawings are not to be considered as drawn to scale unless explicitly noted and some features may be exaggerated for clarity.

### DETAILED DESCRIPTION OF EXEMPLARY EMBODIMENTS

Advantages and objects will become more apparent by describing in detail exemplary embodiments thereof with reference to the attached drawings.

Exemplary embodiments will now be described more fully with reference to the accompanying drawings, in which exemplary embodiments are shown.

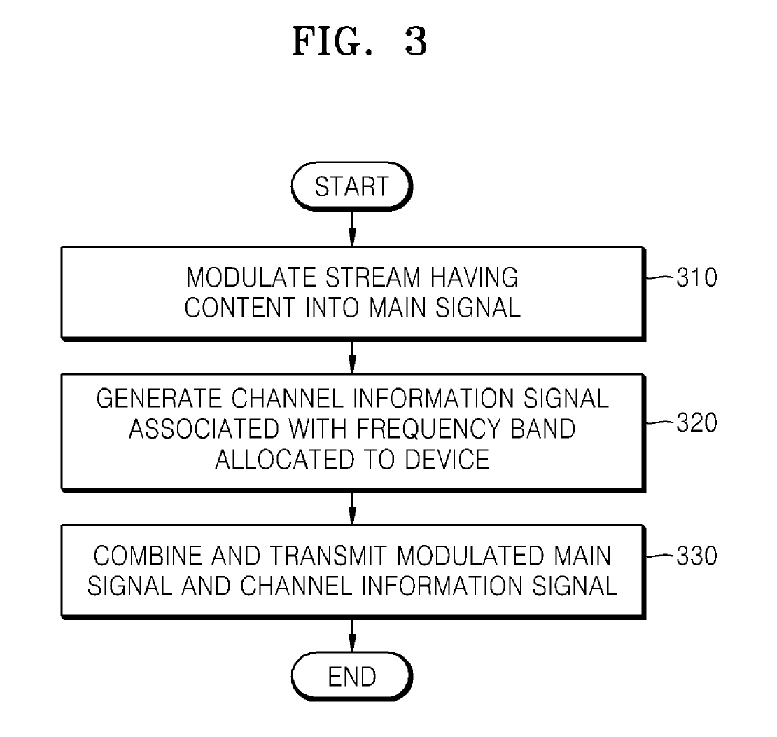

FIG. 3 is a flowchart illustrating a method of transmitting frequency channel information, according to an exemplary embodiment.

Referring to FIG. 3, the method includes operation 310 in which a stream having content is modulated into a main signal, operation 320 in which a channel information signal associated with a frequency band allocated to a device is generated, and operation 330 in which the modulated main signal and the channel information signal are combined and transmitted.

In operation 310, the stream having the content is modulated into the main signal. The main signal is a signal having content including primary services such as TV broadcasting services or wireless communication services. A transport stream (TS) containing predetermined content may be modulated by a typical wireless communication method to generate the main signal.

In operation 320, the channel information signal is generated. Channel information includes frequency information within the frequency band allocated to the device. For example, the channel information may include various frequency information, such as information on all frequency bands allocated to the device, information on a frequency channel that is being used, information on a frequency channel that is to be used, information on the type of content provided by the frequency channel that is being used or is to be used, and information on an identifier.

The channel information signal is generated by being separated from the main signal. That is, the channel information signal is not inserted into the main signal to be modulated and transmitted as a transport stream. If the channel information signal is modulated and transmitted as one transport stream, a receiving end should be able to demodulate the main signal, thereby increasing the complexity of a terminal. Also, since various primary services may exist, modules for obtaining information on a plurality of channels corresponding to the various primary services are required. After a plurality of transport streams are multiplexed, they should be modulated.

Accordingly, in FIG. 3, the channel information signal is generated by being separated from the main signal. The channel information signal has a power level less than that of the main signal. If the power level of the channel information signal is higher than that of the main signal, this may affect the performance of the receiving end when the receiving end receives and reproduces the main signal. Accordingly, the channel information signal has a power level low enough not to affect the performance, that is, the error rate of the receiving end. The power level of the channel information signal is less than that of the main signal by a threshold value and the threshold value may be 20 dB. The threshold value may vary within an allowable range of the error rate of the receiving end.

In operation 330, the main signal and the channel information signal are combined and transmitted.

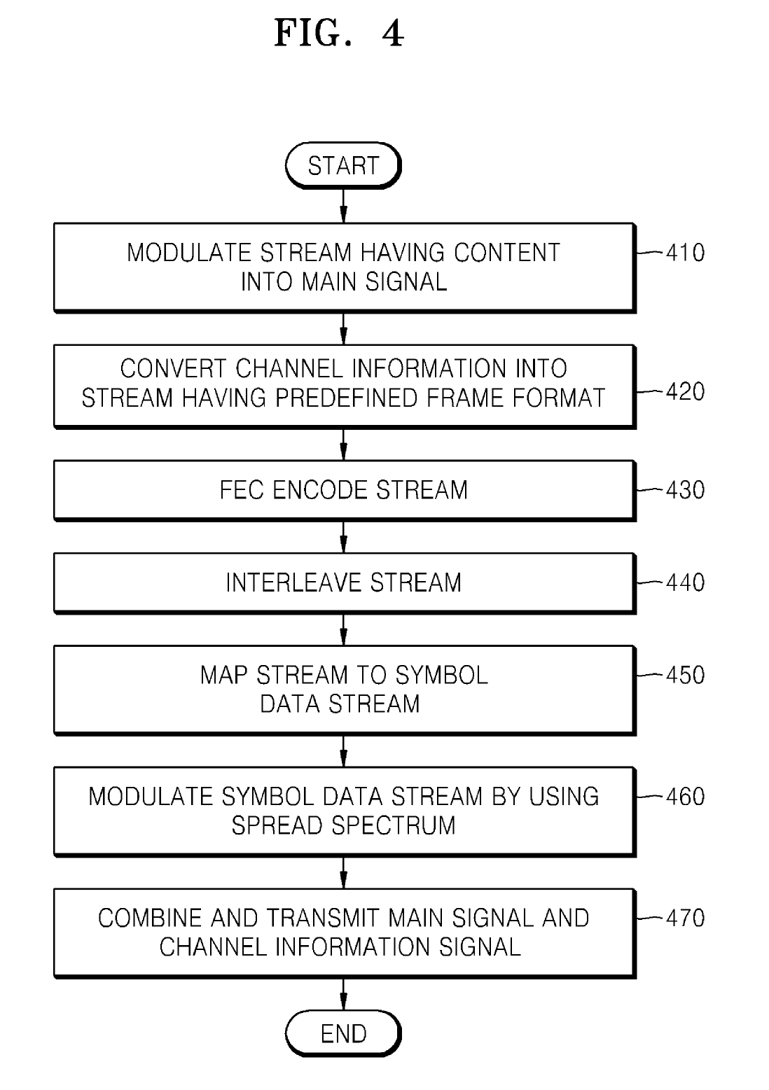

A method of transmitting frequency channel information according to another exemplary embodiment will now be explained with reference to FIG. 4.

FIG. 4 is a flowchart illustrating a method of transmitting frequency channel information, according to another exemplary embodiment.

Referring to FIG. 4, the method includes operation 410 in which a stream having content is modulated into a main signal, operation 420 in which channel information is converted into a stream having a predefined frame format, operation 430 in which the converted stream is forward error correction (FEC) encoded, operation 440 in which the encoded stream is interleaved, operation 450 in which the interleaved stream is mapped into a symbol data stream, operation 460 in which the symbol data stream is modulated by spread spectrum, and operation 470 in which the main signal and the channel information signal are combined and transmitted.

When compared with the method of FIG. 3, operation 410 in which the stream having the content is modulated into the main signal and operation 470 in which the main signal and the channel information signal are combined and transmitted are the same as operations 310 and 330, respectively, and thus a detailed explanation thereof will not be given.

Operation 320 of the method of FIG. 3 may be divided into operations 420, 430, 440, 450, and 460 of the method of FIG. 4. The method of FIG. 4 further includes operation 420 in which the channel information is converted into the stream having the predefined frame format, operation 430 in which the converted stream is FEC encoded, operation 440 in which the encoded stream is interleaved, operation 450 in which the interleaved stream is mapped into the symbol data stream, and operation 460 in which the symbol data stream is modulated by the spread spectrum.

In operation 420, the channel information is converted into the stream having the frame format that is predefined by a receiving terminal for communication.

In operation 430, FEC is a method of controlling propagation errors in a wireless network whereby a transmitter adds an error correction code, e.g., parity bits, to messages and allows a receiver to detect and correct errors in the messages without a need to request the sender to retransmit the messages, thereby providing a high throughput in real time.

In operation 440, interleaving is a method of non-contiguously arranging data in alternating patterns in order to prevent the loss of data through burst errors. Interleaving is often used to improve resistance against impulse noise interference. Interleaving involves re-arranging data units in a data stream such that, even when some bits in the data stream are lost due to impulse noise interference, since bit errors are dispersed, the bit errors can be corrected by the receiving end through deinterleaving.

In operation 450, the interleaved stream is mapped into the symbol data stream by binary phase shift keying (BPSK), quadrature phase shift keying (QPSK), quadrature amplitude modulation (QAM) or the like.

In operation 460, the symbol data stream is modulated by the spread spectrum, such that the channel information signal to be transmitted is spread to increase a processing gain.

That is, spread spectrum is a method of spreading the bandwidth of transmitted data by multiplying the transmitted data by a spreading code having a much higher data rate and wider bandwidth than the transmitted data. Since the energy of the transmitted data is constant, the power is inversely proportional to the increased bandwidth. The name ‘spread spectrum’ comes from the fact that data is transmitted over a wider bandwidth.

Direct sequence spread spectrum, frequency hopping spread spectrum, and time hopping spread spectrum are forms of spread spectrum. Direct sequence spread spectrum is a method of obtaining a spread spectrum signal by directly multiplying data by a spreading code. Frequency hopping spread spectrum is a method of changing a frequency band according to a spreading code. Time hopping spread spectrum is a method of spreading the bandwidth of data along a time axis.

In short, since the method of FIG. 4 modulates the symbol data stream by using the spread spectrum using the spreading code, security can be improved. Since both the spreading and despreading are performed, resistance to external narrow band interference can be improved. Since the widened frequency band offers frequency diversity, resistance to fading can be improved.

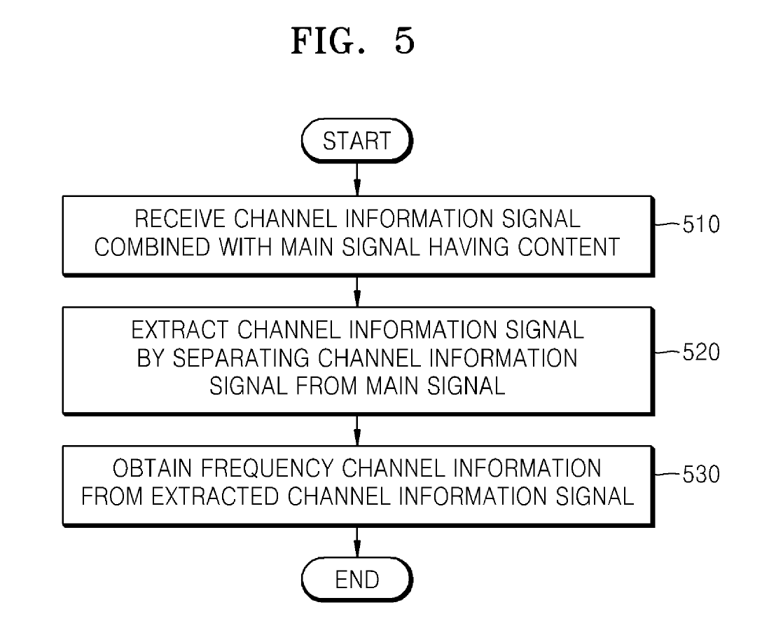

FIG. 5 is a flowchart illustrating a method of receiving frequency channel information, according to an exemplary embodiment.

Referring to FIG. 5, the method includes operation 510 in which a channel information signal combined with a main signal having content is received, operation 520 in which the channel information signal is extracted by separating the channel information signal from the received main signal, and operation 530 in which frequency channel information is obtained from the extracted channel information signal.

In operation 510, the main signal and the channel information signal which are combined with each other are received. However, since a receiving end adopting frequency sharing does not need to demodulate and decode all received signals, only the channel information signal needs to be extracted from among the received signals and then processed.

Accordingly, in operation 520, the main signal and the channel information signal are separated from each other to extract only the channel information signal. The extracting of the channel information signal may further include demodulating the channel information signal into anon-spread spectrum signal by using despread spectrum.

If a transmitting end transmits frequency channel information by using spread spectrum, the receiving end may extract an original signal by multiplying a spread spectrum signal transmitted over a wide bandwidth by a spreading code that is the same as used during transmission. That is, the bandwidth of the spread spectrum signal is reduced to the bandwidth of the original signal through despreading. Since the energy of the data is constant, the power is inversely proportional to the reduced bandwidth, thereby making it possible to separate the channel information signal from the main signal.

The extracting of the channel information signal may further include obtaining synchronization with respect to the channel information signal by using a predefined frame format. The obtaining of the synchronization may be additionally performed to the despreading in which the original signal is separated by using the same spreading code as that used during transmission. If the transmitting end transmits the main signal and the channel information signal at the same start point of time, synchronization information may be obtained by using the frame format of the main signal. Furthermore, even when the main signal and the channel information signal are synchronized over the entire period of time, the receiving end may use the frame format of the main signal to obtain synchronization.

In operation 530, the frequency channel information may be obtained from the extracted channel information signal. The obtained frequency channel information includes frequency information within a frequency band allocated to a transmitting device. For example, the obtained frequency channel information may include various frequency information such as information on all frequency bands allocated to the device, information on a frequency channel that is being used, information on a frequency channel that is to be used, information on the type of content provided by the frequency channel that is being used or is to be used, and information on an identifier. Accordingly, a receiving device can analyze the frequency channel information and share a specific frequency without affecting primary services.

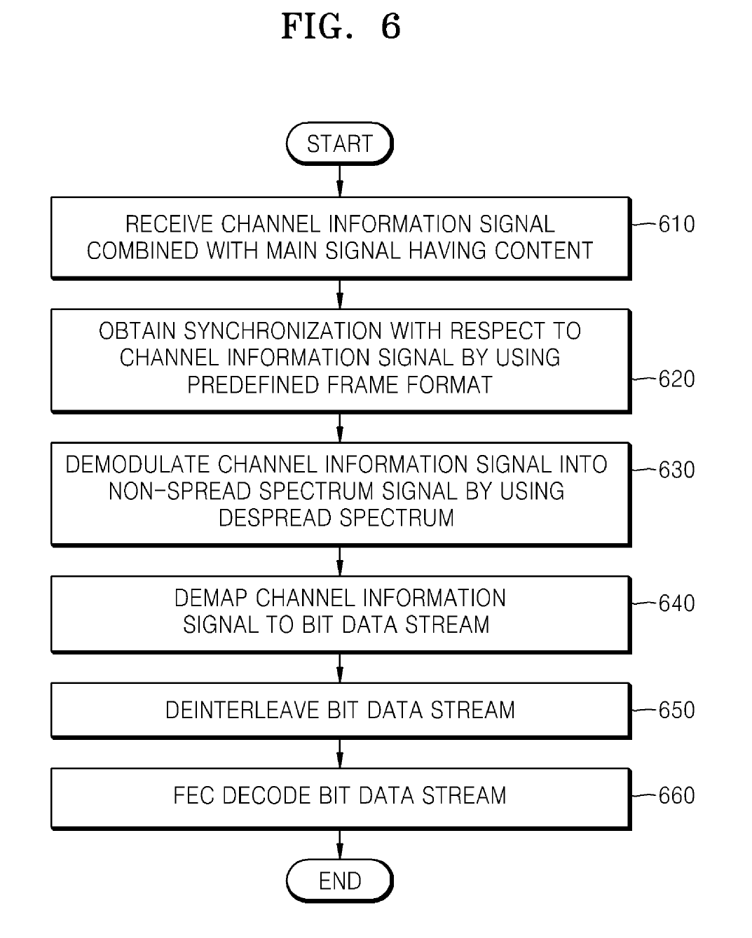

FIG. 6 is a flowchart illustrating a method of receiving frequency channel information, according to another exemplary embodiment.

Referring to FIG. 6, the method includes operation 610 in which a channel information signal combined with a main signal having content is received, operation 620 in which synchronization with respect to the channel information signal is obtained by using a predefined frame format, operation 630 in which the channel information signal is demodulated into anon-spread spectrum signal by using despread spectrum, operation 640 in which the demodulated channel information signal is demapped into a bit data stream, operation 650 in which the bit data stream is deinterleaved, and operation 660 in which the deinterleaved bit data stream is FEC decoded.

Operations 610 through 630 are the same as described above, and thus other operations will now be explained.

When compared with the method of FIG. 5, operation 530 in which the frequency channel information is obtained may be divided into operation 640 in which the demodulated channel information signal is demapped into the bit data stream, operation 650 in which the bit data stream is deinterleaved, and operation 660 in which the deinterleaved bit data stream is FEC decoded.

Operations 640 through 660 are basically performed in reverse order to operations performed by a transmitting end. That is, if the transmitting end FEC encodes a stream, interleaves the encoded stream, and maps the interleaved stream into a symbol data stream, operations 640 and 660 are performed by demapping the transmitted stream into a bit data stream, deinterleaving the bit data stream, and FEC decoding the deinterleaved bit data stream.

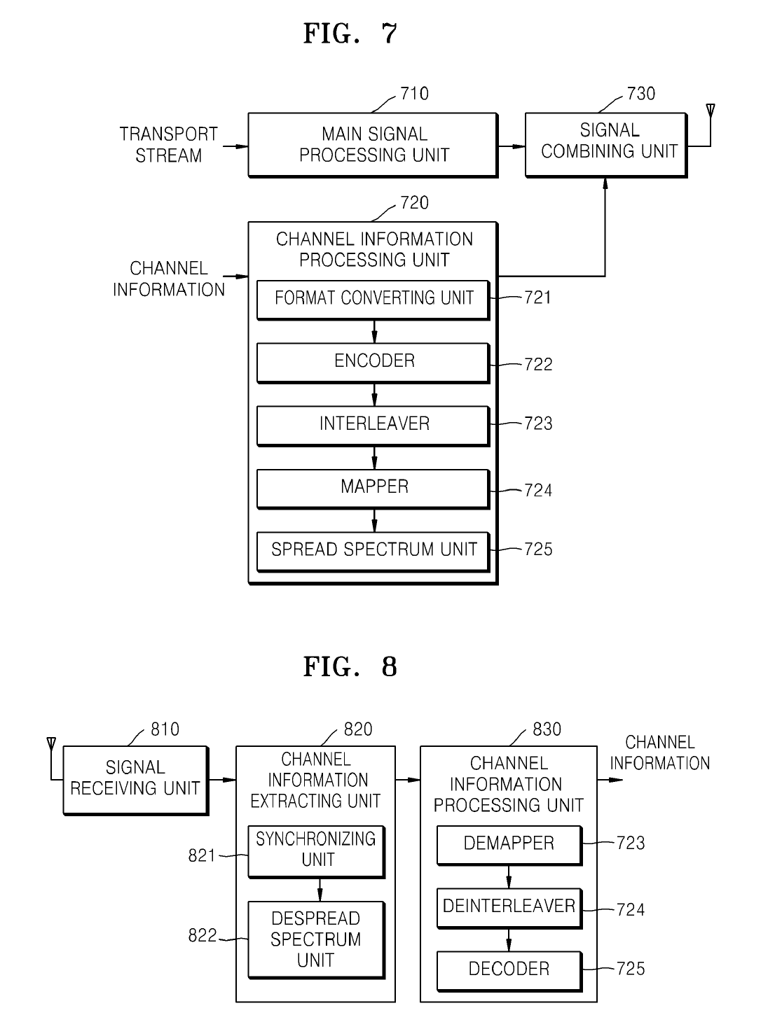

FIG. 7 is a block diagram of an apparatus for transmitting frequency channel information according to an exemplary embodiment.

Referring to FIG. 7, the apparatus includes a main signal processing unit 710 modulating a stream having content into a main signal, a channel information processing unit 720 generating a channel information signal related to a frequency band allocated to a device, and a signal combining unit 730 combining and transmitting the modulated main signal and the channel information signal.

The channel information processing unit 720 may further include a format converting unit 721 converting channel information into a stream having a predefined frame format, an encoder 722 FEC encoding the converted stream, an interleaver 723 interleaving the encoded stream, a mapper 724 mapping the interleaved stream into a symbol data stream, and a spread spectrum unit 725 modulating the symbol data stream by using spread spectrum.

FIG. 8 is a block diagram of an apparatus for receiving frequency channel information according to an exemplary embodiment.

Referring to FIG. 8, the apparatus includes a signal receiving unit 810 receiving a channel information signal combined with a main signal having content, a channel information extracting unit 820 extracting the channel information signal by separating the channel information signal from the received main signal, and a channel information processing unit 830 obtaining frequency channel information from the extracted channel information signal.

The channel information extracting unit 820 may further include a synchronizing unit 821 obtaining synchronization with respect to the channel information signal by using a predefined frame format, and a despread spectrum unit 822 demodulating the channel information signal into anon-spread spectrum signal by using despread spectrum. If a transmitting end transmits the main signal and the channel information signal at the same start point of time, the synchronizing unit 821 may obtain synchronization with respect to the channel information signal by using the frame format of the main signal.

The channel information processing unit 830 may further include a demapper demapping the demodulated channel information signal into a bit data stream, a deinterleaver deinterleaving the bit data stream, and a decoder FEC decoding the deinterleaved bit data stream.

The apparatus may be applied to various wireless systems using frequency sharing such as a mobile phone, an MP3 player, or a personal computer (PC) or a television (TV) using a wireless local area network(WLAN).

As described above, the method and apparatus for transmitting and receiving the frequency channel information according to exemplary embodiments can implement frequency sharing without affecting existing primary services. The method and apparatus according to exemplary embodiments can use frequency sharing for various primary services by enabling a terminal device to obtain information on a used frequency band without increasing the complexity of the terminal device.

The method and apparatus according to exemplary embodiments may be written as computer programs and can be implemented in general-use digital computers that execute the programs using a computer readable recording medium.

The structure of data used by exemplary embodiments may be recorded through various means on a computer-readable recording medium as described above.

Examples of non-transitory computer-readable medium include storage media such as magnetic storage media (e.g., read only memories (ROMs), floppy discs, or hard discs), optically readable media (e.g., compact disk-read only memories (CD-ROMs), or digital versatile disks (DVDs)). Other types of computer-readable medium include, for example, carrier waves (e.g., transmissions over the Internet).

While exemplary embodiments have been particularly shown and described using specific terms, the exemplary embodiments should not be construed as limiting the scope of the present invention defined by the claims. Accordingly, it will be understood by one of ordinary skill in the art that various changes in form and details may be made therein without departing from the spirit and scope of the present invention as defined by the following claims.

1. A method of transmitting frequency channel information by a device to which a frequency band is allocated, the method comprising:
modulating a stream having content into a main signal; generating a channel information signal related to the frequency band allocated to the device; and
combining and transmitting the modulated main signal and the channel information signal.

2. The method of claim 1, wherein the generating of the channel information signal comprises generating the channel information signal as a separate signal from the modulated main signal.

3. The method of claim 2, wherein the generated channel information signal has a power level less than that of the main signal based on a predetermined threshold value.

4. The method of claim 3, wherein the threshold value is an experimental value that does not change an error rate of the main signal and is higher than 20 dB.

5. The method of claim 3, wherein the generating of the channel information signal further comprises modulating channel information by using spread spectrum.

6. The method of claim 5, wherein the generating of the channel information signal further comprises:
converting the channel information into a stream having a predefined frame format;
forward error control (FEC) encoding the converted stream;
interleaving the encoded stream; and
mapping the interleaved stream into a symbol data stream.

7. A method of receiving frequency channel information by a second device that shares a frequency band allocated to a first device, the method comprising:
receiving a channel information signal combined with a main signal having content;
extracting the channel information signal by separating the channel information signal and the received main signal; and
obtaining frequency channel information from the extracted channel information signal.

8. The method of claim 7, wherein the received channel information signal has a power level less than that of the main signal based on a predetermined threshold value.

9. The method of claim 8, wherein the threshold value is an experimental value that does not change an error rate of the main signal and is higher than 20 dB.

10. The method of claim 8, wherein the extracting of the channel information signal further comprises demodulating the channel information signal into a non-spread spectrum signal by using a despread spectrum.

11. The method of claim 10, wherein the extracting of the channel information signal further comprises obtaining synchronization with respect to the channel information signal by using a predefined frame format of the channel information signal.

12. The method of claim 10, wherein, if the first device synchronizes the main signal with the channel information signal at a same start point of time, the extracting of the channel information signal further comprises obtaining synchronization with respect to the channel information signal by using a frame format of the main signal.

13. The method of claim 11, wherein the obtaining of the frequency channel information further comprises:
demapping the demodulated channel information signal into a bit data stream;
deinterleaving the bit data stream; and
FEC decoding the deinterleaved bit data stream.

14. An apparatus for transmitting frequency channel information by a device to which a frequency band is allocated, the apparatus comprising:
a main signal processing unit modulating a stream having content into a main signal;
a channel information processing unit generating a channel information signal related to the frequency band allocated to the device; and
a signal combining unit combining and transmitting the modulated main signal and the channel information signal.

15. The apparatus of claim 14, wherein the channel information processing unit generates the channel information signal as a separate signal from the modulated main signal.

16. The apparatus of claim 15, wherein the generated channel information signal has a power level less than that of the main signal based on a predetermined threshold value.

17. The apparatus of claim 16, wherein the threshold value is an experimental value that does not change an error rate of the main signal and is higher than 20 dB.

18. The apparatus of claim 16, wherein the channel information processing unit further comprises a spread spectrum unit modulating channel information by using spread spectrum.

19. The apparatus of claim 18, wherein the channel information processing unit further comprises:
a format converting unit converting the channel information into a stream having a predefined frame format;
an encoder FEC encoding the converted stream;
an interleaver interleaving the encoded stream; and
a mapper mapping the interleaved stream into a symbol data stream.

20. An apparatus for receiving frequency channel information by a second device that shares a frequency band allocated to a first device, the apparatus comprising:
a signal receiving unit receiving a channel information signal combined with a main signal having content;
an extracting unit extracting the channel information signal by separating the channel information signal and the received main signal; and
a channel information processing unit obtaining frequency channel information from the extracted channel information signal.

21. The apparatus of claim 20, wherein the received channel information signal has a power level less than that of the main signal based on a predetermined threshold value.

22. The apparatus of claim 21, wherein the threshold value is an experimental value that does not change an error rate of the main signal and is higher than 20 dB.

23. The apparatus of claim 21, wherein the extracting unit further comprises a despread spectrum unit demodulating the channel information signal into a non-spread spectrum signal by using a despread spectrum.

24. The apparatus of claim 23, wherein the extracting unit further comprises a synchronizing unit obtaining synchronization with respect to the channel information signal by using a predefined frame format.

25. The apparatus of claim 23, wherein, if the first device transmits the main signal and the channel information signal at a same start point of time, the extracting unit further comprises a synchronization unit obtaining synchronization with respect to the channel information signal by using a frame format of the main signal.

26. The apparatus of claim 24, wherein the channel information processing unit comprises:
a demapper demapping the demodulated channel information signal into a bit data stream;
a deinterleaver deinterleaving the bit data stream; and
a decoder FEC decoding the deinterleaved bit data stream.
